(19) United States
(12) Patent Application Publication
(10) Pub. No.: US 2015/0118626 A1
(43) Pub. Date: Apr. 30, 2015

(54) TUBE NOZZLE ELECTROSPINNING

(71) Applicant: University of Florida Research Foundation, Inc., Gainesville, FL (US)

(72) Inventors: Yong-Kyu Yoon, Gainesville, FL (US); Pit Fee Jao, Albuquerque, NM (US)

(73) Assignee: University of Florida Research Foundation, Inc., Gainesville, FL (US)

(21) Appl. No.: 14/403,389

(22) PCT Filed: May 31, 2013
(86) PCT No.: PCT/US2013/043652

§ 371 Date: Nov. 24, 2014

Related U.S. Application Data
(60) Provisional application No. 61/653,615, filed on May 31, 2012.

(51) Int. Cl. D01D 5/00; G03F 7/20; C01B 31/02

(52) U.S. Cl. CPC D01D 5/0076; D01D 5/0007; C01B 31/0206; G03F 7/2002
USPC 430/322; 425/162; 425/174.8 E; 264/465

(57) ABSTRACT

Various examples are provided for tube nozzle electrospinning. In one example, among others, is a system including a nozzle tube with an array of nozzles configured to produce a plurality of electrospun nanofibers and a positioning stage configured to control deposition of the plurality of electrospun nanofibers on a substrate to form a layer of nanofibers. Another example is a method including generating a plurality of electrospun nanofibers from an array of nozzles positioned over a substrate and controlling movement of the substrate to form a layer of electrospun nanofibers.

### CROSS REFERENCE TO RELATED APPLICATIONS

This application claims priority to co-pending U.S. provisional application entitled “TUBE NOZZLE ELECTROSPINNING” having Ser. No. 61/653,615, filed May 31, 2012, the entirety of which is hereby incorporated by reference.

### STATEMENT REGARDING FEDERALLY SPONSORED RESEARCH OR DEVELOPMENT

This invention was made with government support under agreement ECCS 1132413 awarded by the National Science Foundation. The Government has certain rights in the invention.

### BACKGROUND

Nanoscale functional materials have applications in various fields such as, e.g., electronics, optics, energy, medicine, and biology. Nanoscale functional materials can include various morphologies ranging from films and fibers to cones and coaxial spheres. Applications for the various morphologies can include, e.g., gas sensors that utilize large surface areas, nerve guidance scaffolds using aligned biodegradable polymers, air filters with small pore sizes, nano sensors requiring low dimensionality, super capacitors, and dye sensitized solar cells (DSSC).

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 is a graphical representation of an example of a system for single needle electrospinning (SNE) in accordance with various embodiments of the present disclosure.

FIGS. 2A and 2B are graphical representations of an example of a system for tube nozzle electrospinning (TNE) in accordance with various embodiments of the present disclosure.

FIG. 3 is a schematic diagram illustrating lithographic patterning of the electrospun nanofibers produced by TNE in accordance with various embodiments of the present disclosure.

FIGS. 4 and 5 illustrate examples of tube nozzle placement in the tube nozzle of FIGS. 2A and 2B in accordance with various embodiments of the present disclosure.

FIGS. 6 and 7 are scanning electron microscopy (SEM) images of examples of electrospun nanofibers collected at variable operating conditions of the TNE system of FIGS. 2A and 2B in accordance with various embodiments of the present disclosure.

FIGS. 8 and 9 are plots illustrating examples of nanofiber diameter variations under different operating conditions of the TNE system of FIGS. 2A and 2B in accordance with various embodiments of the present disclosure.

FIG. 10 is images of examples of electrospun nanofibers collected at variable operating conditions of the TNE system of FIGS. 2A and 2B in accordance with various embodiments of the present disclosure.

FIG. 11 is a plot illustrating variation in porosity under different operating conditions of the TNE system of FIGS. 2A and 2B in accordance with various embodiments of the present disclosure.

FIGS. 12A and 12B illustrate examples of electric field streamlines and electric field strength of SNE needle and TNE nozzle assemblies in accordance with various embodiments of the present disclosure.

FIG. 13 includes images of the Taylor cone formation at nozzles of a nozzle tube of the TNE system of FIGS. 2A and 2B in accordance with various embodiments of the present disclosure.

FIG. 14 includes examples of histograms of nanofiber diameter distributions produced by the TNE system of FIGS. 2A and 2B in accordance with various embodiments of the present disclosure.

FIG. 15 is a plot illustrating the thickness of nanofiber stacks collected with the TNE system of FIGS. 2A and 2B in accordance with various embodiments of the present disclosure.

FIG. 16 is an image of an example of the TNE system of FIGS. 2A and 2B in accordance with various embodiments of the present disclosure.

FIGS. 17 and 18 include images of patterned electrospun nanofibers produced by the TNE system of FIGS. 2A and 2B in accordance with various embodiments of the present disclosure.

FIG. 19 is a graphical representation of an example of a super capacitor (SC) in accordance with various embodiments of the present disclosure.

FIG. 20 depicts an example of a SC fabrication process using TNE in accordance with various embodiments of the present disclosure.

FIG. 21 is an image of carbonized electrospun nanofibers produced by the TNE system of FIGS. 2A and 2B in accordance with various embodiments of the present disclosure.

FIG. 22 is a plot illustrating the diameter shrinkage observed in the carbon nanofibers of FIG. 21 in accordance with various embodiments of the present disclosure.

FIG. 23 is a plot illustrating the shrinkage of the thickness of an electrospun nanofiber membrane with carbonization in accordance with various embodiments of the present disclosure.

FIG. 24 includes images of an unpackaged SC and a cross-sectional of the fabricated SC in accordance with various embodiments of the present disclosure.

### DETAILED DESCRIPTION

Disclosed herein are various embodiments related to tube nozzle electrospinning. Reference will now be made in detail to the description of the embodiments as illustrated in the drawings, wherein like reference numbers indicate like parts throughout the several views.

Nanoscale functional materials may be produced using electrospinning. Electrospinning is the process of electrostatically charging a polymer solution to a high voltage, dispensing the charged polymer solution with electrostatic force, and collecting the fibers that are produced at a grounded collector. The highly charged solution splits into very fine and long nanofibers, as it travels in air to the collector, thus collecting as a web of interconnected nanofibers. Electrospinning can generate a multitude of nanoscale fibers from a number of electrospunnable polymer melts or solutions in a matter of seconds. Properties of the nanofiber morphology include, e.g., large surface area to volume ratio, flexibility of fabricated devices, and other superior mechanical properties.

A typical electrospinning process begins with the formation of a hemispherical droplet at the tip of a conductive electret or needle. At that moment, the surface tension at the surface of the droplet is much larger than the columbic attractive force of the external field. As the droplet grows, more charges are collected at the tip of the needle and the mutual electrostatic repulsion forces dominate, which elongates the droplet in the shape of a cylindrical cone known as the Taylor cone. The Taylor cone continues to elongate until a critical point is reached. At the critical point, the electrostatic forces are larger than the surface tension and a liquid jet is initiated from the tip of the cone. The jet elongates as it travels towards the collector. As the jet travels, it continues to elongate while it shrinks in diameter due to the evaporation of solvents in the fibers. The jet experiences a bending stability at a critical point between the needle and collector where the jet starts whipping in multiple directions in a chaotic fashion producing a web of non-woven fibers. Single needle electrospinning (SNE) uses a single needle as the source of the polymer droplet in the electrospinning setup.

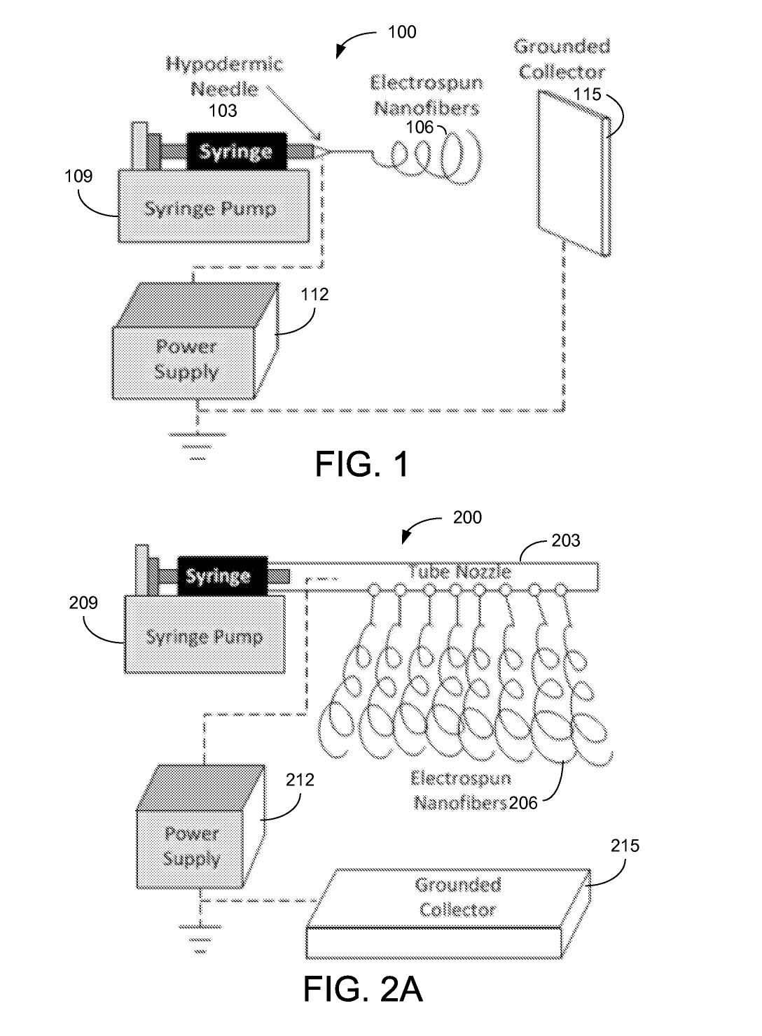

Referring to FIG. 1, shown is a graphical representation of an example of a SNE system 100. The SNE system 100 of FIG. 1 includes a syringe with a hypodermic needle 103 for producing electrospun nanofibers 106, a syringe pump 109, a power supply 112, and a grounded collector 115. Fiber material (e.g., SU8 or other prepared polymer solution) is loaded into the syringe without the introduction of bubbles and capped with the hypodermic needle 103 (e.g., a 21 gauge stainless steel hypodermic needle, CML Supply LLC, USA). The syringe is then loaded into the precision syringe pump 109 (e.g., NE-1000, New Era Pump Systems Inc.), which is programmed to pump at a specified rate. The fiber material can be charged via a copper insert with the high voltage power supply 112 (e.g., 603C-300P, Spellman High Voltage Electronic Co.). The solution can be pumped with a steady flow, which is maintained using the syringe pump 109. Operating conditions for SU8 electrospinning can include a needle voltage of about 12.5 kV, a tip-to-collector distance (TCD) of about 12.5 cm, and a flow rate of about 0.2 ml/min for the SNE approach. Operating conditions may be varied. For example, the needle voltage may be varied in a range of about 10 kV to about 15 kV (or up to 30 kV), the flow rate may be adjusted to 0.5 ml/hr, and/or the TCD may be varied from about 7.5 cm to about 12.5 cm.

Multiple jet electrospinning can be used to achieve a higher liquid throughput of nanofibers. An electro hydrodynamic (EHD) instability can be generated on the surface of the polymer to generate multiple jetting points to initiate the electrospinning process. In multineedle electrospinning (MES), multiple spinnerets can be generated using a linear or matrix array of multiple single needles. For example, a linear array of 7 or 9 metallic needles can be used. The electrospinning performance depends on the inter needle spacing and the tip-to-collector distance. Jet-to-jet repulsion experienced with closely spaced needles suggested a minimum spacing between needles of about 1 cm, below which the periphery needles observe a deflection towards the outside. In larger arrays (e.g., a linear array of 26 needles), it was observed that only the outer needles produced fibers whereas the inner needles produced droplets. This phenomenon may be attributed to electric field shielding associated with the high density of needles used. In the case of multiple metallic needles, electric field simulations have shown that the discrete electrodes act as the point of divergent electric fields. The columbic repulsion of nanofibers pushes the cone of electrospun nanofibers away, resulting in a non-uniform collection of nanofibers. To minimize the electric field effect, distributed architectures with a two dimensional multineedle layout may be used. Divergent electric fields in MES may also be suppressed with the use of external electrodes. Elliptical and concentric architectures may be employed to minimize the jet repulsion effect and to achieve uniformity and compact electrospinning.

Needleless electrospinning (NES) can be achieved using a rotating drum placed halfway in a large open polymer and continuously entrailing a thin polymer film onto its periphery. An electric field applied between the drum and a grounded plate ejects nanofibers from the surface of the drum to produce multiple nanofibers. Some electrospinning jets were produced by using an immiscible magnetic layer below the polymer or by controlled gas bubbles from the underneath polymer surface. Electrospinning jets may be formed with lower initiating voltages by reducing the surface tension at the spinnerets and the polymer bath.

Tube nozzle electrospinning (TNE) is a technique for producing large scale electrospun nanofibers. TNE provides a high throughput nanofiber fabrication process using, e.g., photopatternable epoxy SUB. In TNE, low density polyethylene (LDPE) tubes are adapted using a computer numerical control (CNC) milling machine to form a linear nozzle array. Electric field effects between nozzles, nanofiber production rate as a function of the nozzle count, and photopatterning of the electrospun nanofiber stacks are discussed.

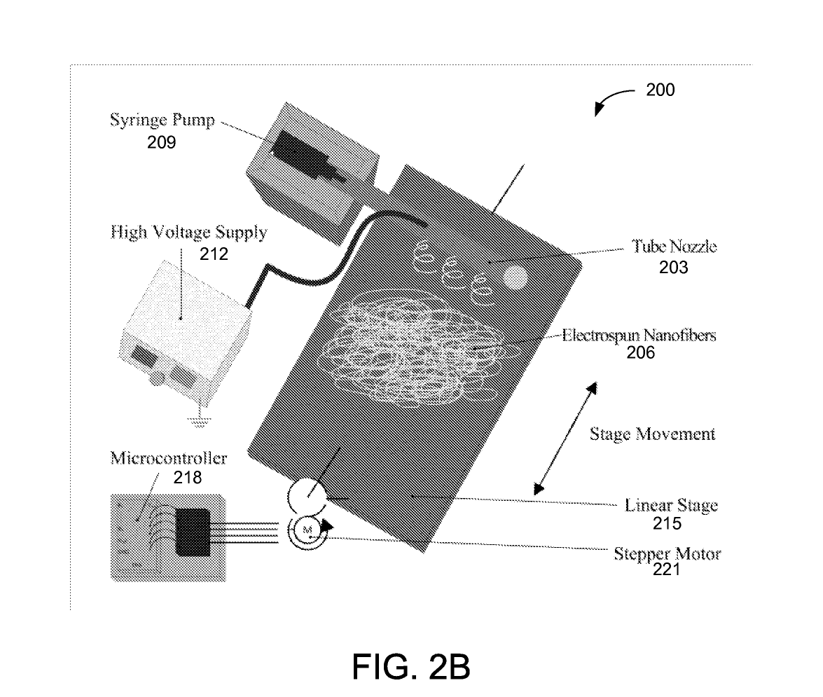

Referring to FIGS. 2A and 2B, shown are graphical representations of an example of a system for TNE. As shown in FIG. 2A, the TNE system 200 includes a tube nozzle 203 fabricated with multiple nozzles through which electrospun nanofibers 206 are generated and collected on a grounded collector 215. A syringe pump 209 is used to provide fiber material to the tube nozzle 203 at a controlled rate. A power supply 212 maintains a charge on the fiber material. Referring to FIG. 2B, the syringe pump 209 of the TNE system 200 provides the fiber material through the tube nozzle 203 to the nozzles for ejection. For example, polymer solution may be supplied to the tube nozzle 203 from the syringe using a Luer lock connector. The tube nozzle 203 may be a straight low density polyethylene (LDPE) tube that includes nozzles on one side, which extend to the inside of the tube. The multiple nozzles are used in place of a single metallic needle, thus producing a multi-fold increase in the generated nanofiber throughput. The high voltage supply 212 maintains voltage on the tube nozzle 203. The electrospun nanofibers 206 are deposited on a stage 215 (e.g., a grounded collector plate or stage). With the nozzles facing downwards, can be collected on the grounded substrate (or stage) 215 placed below the tube.

Referring to FIG. 2B, the use of an automated collector stage 215 (e.g., a linear stage) with a pre-programmed movement allows for uniform collection of nanofibers based on experimental space and time limitations in the electrospinning of, e.g., SU8 nanofibers. The electrospun nanofibers 206 may be deposited on a substrate (e.g., a silicon substrate) affixed to the collector stage 215. Large scale electrospinning can be achieved with horizontal movement of the collector substrate 215 to uniformly distribute the electrospun fibers 206. A microcontroller 218 may be used to control the movement of the collector stage 215 through, e.g., a stepper motor 221 or other drive unit such as linear motor. For example, the linear collector stage 215 may be driven by a stepper motor actuated using a ATmega328 microcontroller (Arduino UNO, SparkFun Electronics, USA) and a stepper motor driver circuit (EasyDriver 4.2, SparkFun Electronics, USA).

The electrospun nanofibers 206 can be patterned to form desired shapes by means of microfabrication processes. For instance, electrospun nanofibers 206 can be patterned in a microscopic scale by means of stamp-thru-molding. When photosensitive polymers are used for electrospinning, the resultant electrospun nanofibers 206 can be photolithographically patterned. In some cases, laser machined patterns may also be produced from the electrospun nanofibers 206.

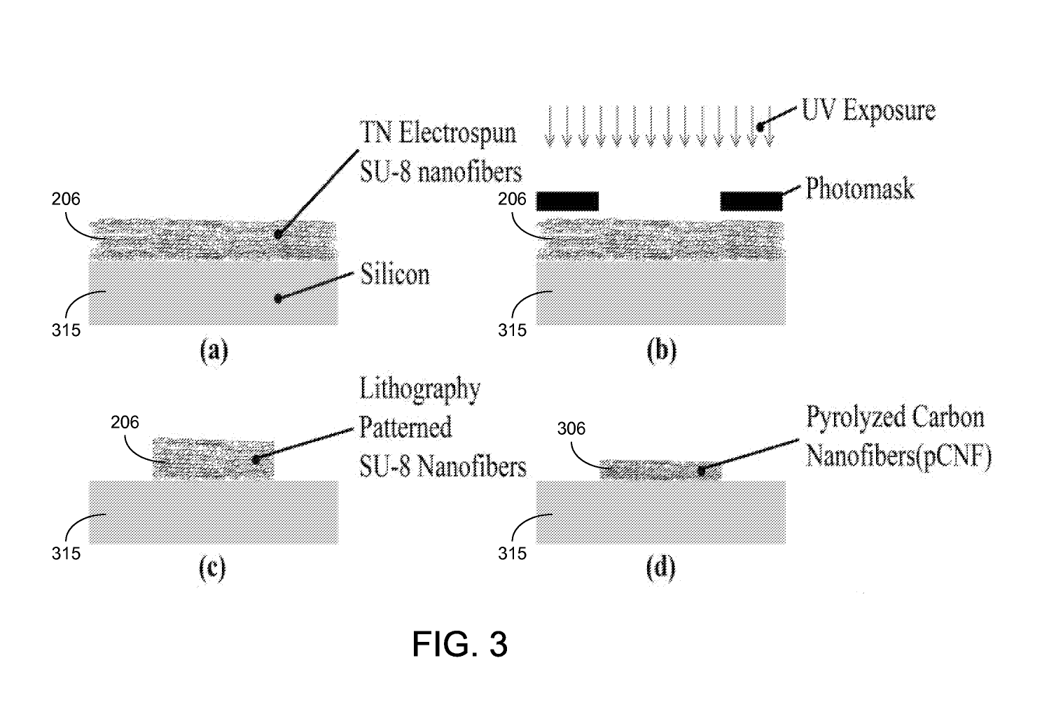

Referring to FIG. 3, shown is a schematic diagram illustrating lithographic patterning of the electrospun nanofibers 206. Beginning with FIG. 3(a), the electrospun nanofibers 206 are initially deposited on a silicon substrate (or wafer) 315 (e.g., p type, University Wafers Inc., USA) using TNE. Thick nanofiber stacks may be collected using the TNE process on a silicon wafer 315 placed on the grounded collector 215 (FIGS. 2A and 2B). In FIG. 3(b), a photomask 318 is formed over the electrospun nanofibers 206 to provide the desired shapes and lithography patterning of the electrospun nanofibers 206 is then performed using a standard 365 nm i-line ultra violet (UV) mask aligner (MA6, Karl Suss Inc., USA) following standard processing conditions. For example, lithographic patterning can be performed using i-line exposure through a chrome patterned glass mask to define patterns in the nanofiber stack. UV exposure dosage can be based on the standard dose recommended for the fiber material (e.g., SU8 or other appropriate polymer). Controlled development in SU8 devebper by immersion and rinse processes can remove the unexposed photoresist covered nanofibers 206 as shown in FIG. 3(c). Following the development of the exposed electrospun nanofibers 206, the sample can be blow dried and/or baked in an oven to remove any trapped solvent. As shown in FIG. 3(d), pyrolyzed carbon nanofibers 306 may be formed by carbonization of SU8 nanofibers in a tube furnace (Lindberg tube furnace, Fisher Scientific, USA) with an inert atmosphere of forming gas (H2:N2 5%:95%) at 1000° C.

In one embodiment, among others, exposure dosage was based on the standard dose recommended for the SU8 film on the data sheet (Microchem Inc.). A UV mask aligner (MA6 Karl Suss Inc.) with i-line (wavelength: 365 nm) was used and a dose of 240 mJ/cm² was used for a 80 μm thick membrane. Samples were then post exposure baked and developed using propylene glycol methyl ether acetate (PGMEA) based SU8 developer for 10 mins. Samples were blow dried with nitrogen and baked at 150° C. to remove any remaining solvents for post processing characterization and imaging.

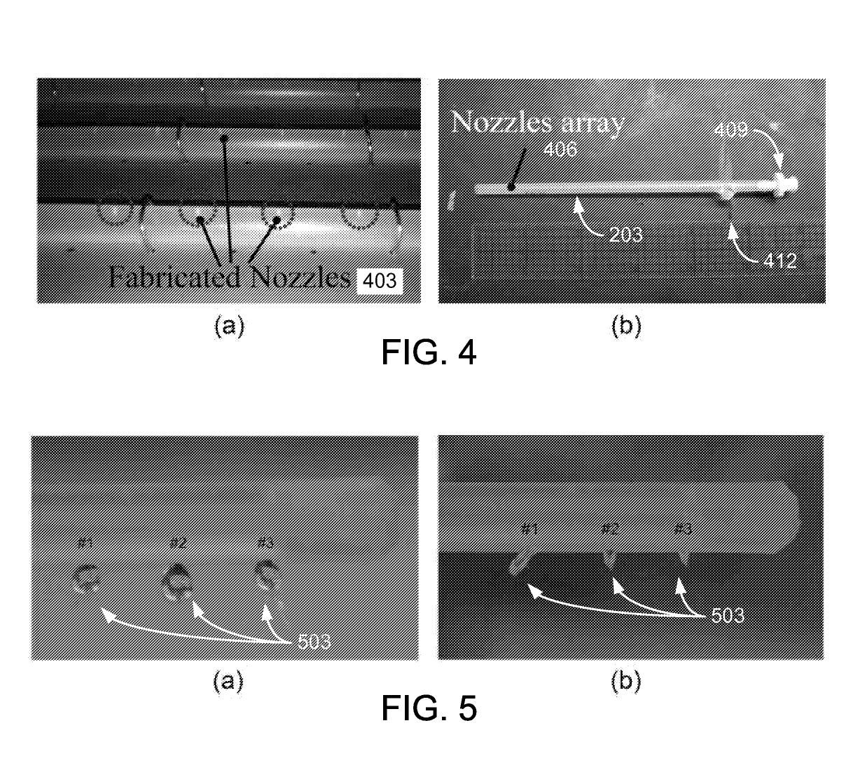

Referring next to FIG. 4, shown are examples of the fabricated tube nozzles 403 on the tube nozzle 203 with variable diameter and pitch configurations for generating nanoporous membranes with variable nanofiber diameters, membrane porosity and fiber distributions. In FIG. 4(a), LDPE tubes are aligned and held in place on a printed circuit board (PCB). In other implementations, the tube nozzle material may include plastic or other non-conductive materials, as well as conductive and semi-conductive tube materials. Nozzle diameters and positions were laid out on a Computer Aided Design (CAD) file and drilled using a Prototyping Machine (LPKF Milling Machine) to give an accurate rendition of the nozzles. Nozzle diameter and pitch may be varied for different sizes of electrospun fibers 206. For example, nozzle diameters may be 0.2 mm or 0.5 mm with a pitch of 0.5 mm, 1 mm, 5 mm, 10 mm, or more. Nozzle diameters may be in a range from about 0.1 mm to about 1 mm with a nozzle-to-nozzle pitch in a range of about 0.5 to about 15 mm. Other nozzle diameters and pitches may also be used.

FIG. 4(b) shows the tube nozzle 203 with a nozzle array 406 on one end and a luer lock connection 409 on the other end for connection to the syringe. In one embodiment, among others, the tube nozzle 203 may be a straight 12.5 cm long LDPE tube (e.g., LDPE01 tubing, Value Plastics Inc. USA) which includes custom fabricated nozzles. A copper wire 412 is inserted into the tube nozzle 203 on the luer lock end and the hole sealed using epoxy for electrical connection. The nozzle end was terminated by thermal sealing. TNE, given its non-metallic nozzles 403, requires a higher electric field (e.g., supplied by the high voltage supply 212 of FIGS. 2A and 2B) to initiate the electrospinning when compared to the same conditions when used with the SNE approach.

Referring to FIG. 5, shown are examples of the effect of increased voltage on the formation of the Taylor cone during the genesis of electrospinning. The example of FIG. 5 is a three nozzle configuration with a 5 mm pitch. At higher operating voltages, the electric field overcomes the forces due to surface tension and transitions from the liquid droplet to the Taylor cone. FIG. 5(a) depicts the effect of operating voltage on the formation of Taylor cones 503 at the nozzle tip prior to the initiation of electrospinning with a nozzle voltage of Vₙ=12.5 kV, a tip-to-collector distance of TCD=12.5 cm, and an electric field of Eₙ=1 kV/cm. FIG. 5(b) depicts the effect on the Taylor cones 503 with a nozzle voltage of Vₙ=15 kV, a tip-to-collector distance of TCD=12.5 cm, and an electric field of Eₙ=1.2 kV/cm.

As seen in FIG. 5, each jet produced from the nozzle tips experiences a mutual repulsion to its neighboring jets. This repulsion is brought about by the columbic repulsion forces acting on the nanofibers due to the charged particles trapped in the solution and also the electric field acting between the tube nozzle and the ground plate. Unlike MES with multiple metallic tips, jets from the insulted nozzle tips observe lesser repulsion due to the absence of the strong electric field repulsion associated with the metallic tips. For nozzle tips with a pitch spacing of 1 cm, no repulsion of jets is observed as it is the specified minimum distance of MES. But in the case of a 5 mm pitch, as shown in FIG. 5(a), a slight repulsion of the jets is observed due to the close proximity of the jets. This repulsion tends to increase the diameter of the cone 503 of electrospun nanofibers 206 (FIGS. 2A and 2B) and thus produces less dense fibers when compared to electrospun nanofibers 206 produced with a 10 mm pitch.

Verification of TNE was carried out using various system configurations. To begin, nozzle diameters were 0.2 mm and 0.5 mm and the nozzle-to-nozzle pitch was either 0.5 mm or 1 mm. The nozzle layout was designed using a CAD layout tool (AutoCAD 2012 Student Edition, Autodesk Inc. USA) and fabricated using a PCB Prototyping machine (ProtoMat S100, LPKF Laser & Electronics AG, Germany). As shown in FIG. 4(b), one end of the tube nozzle 203 was sealed and the other end was connected to the syringe with a luer lock connector 409. The fiber material used in the electrospinning process was photopatternable epoxy SU-8 2025 (Microchem Inc.) diluted in cyclopentanone (Sigma Aldrich Inc.) to give a solution concentration of 60.87 wt %. The polymer solution was prepared by magnetically stirring the contents in an air tight bottle overnight to give a homogeneous solution. The experiments were carried out at room temperature inside an acrylic chamber.

Using the three nozzle configuration of FIG. 4, SU8 nanofibers were successfully electrospun using TNE. It was observed that the jets leaving the nozzle tips have a similar bending instability as that observed in SNE. Bending instability in the SNE process is brought about with the interaction of the electric field repulsion and coulomb repulsion forces at the tip of the metal needle. When sufficiently large, this force will overcome the surface tension of the polymer solution to cause the liquid surface to break, thus causing the instability. It was observed that an electric field of about 1 kV/cm was needed to initiate the electrospinning process. As shown in FIG. 5(a), when the solution is subject to a nozzle voltage of 12.5 kV and a TCD of 12.5 cm, the solution grows spherically until its surface tension decreases and is able to be overcome the forces resisting electrospinning. In the case of FIG. 5(b), where a nozzle voltage of 15 kV and a TCD of 12.5 cm produced an electric field of 1.2 kV/cm, the polymer at the tip of the nozzle is shown to rapidly deform into a Taylor cone 503 and begin electrospinning. Simultaneous electrospinning of all the nozzles did occur. An occasional stop in electrospinning in one of the nozzles was also observed from time to time. For TNE, a slightly higher operating voltage is needed when the using an insulating surface with the same TCD.

Nanofiber characterization was performed to determine the morphology and dimensions using a scanning electron microscope (SEM) (JEOL 5700, JEOL Ltd., USA). Nanofiber diameter and porosity measurements were also performed using Image Processing software (ImageJ, National Institute of Health, USA). Briefly, grayscale SEM images of the sample, were statically measured for their pixel intensity distribution and their mean (μ) and standard deviation (σ) values were noted. To convert to a binary image, the threshold value was selected to be (μ−0.75σ)/255, which was selected based on numerous iterations with all samples. The selected threshold value corresponds to the porosity of all the layers in the stack. Binary hole removal was used to remove noise in the image. Measurements were set to read the calculated pixel intensity and area of the region of interest (ROI) and to tabulate the results in a summary.

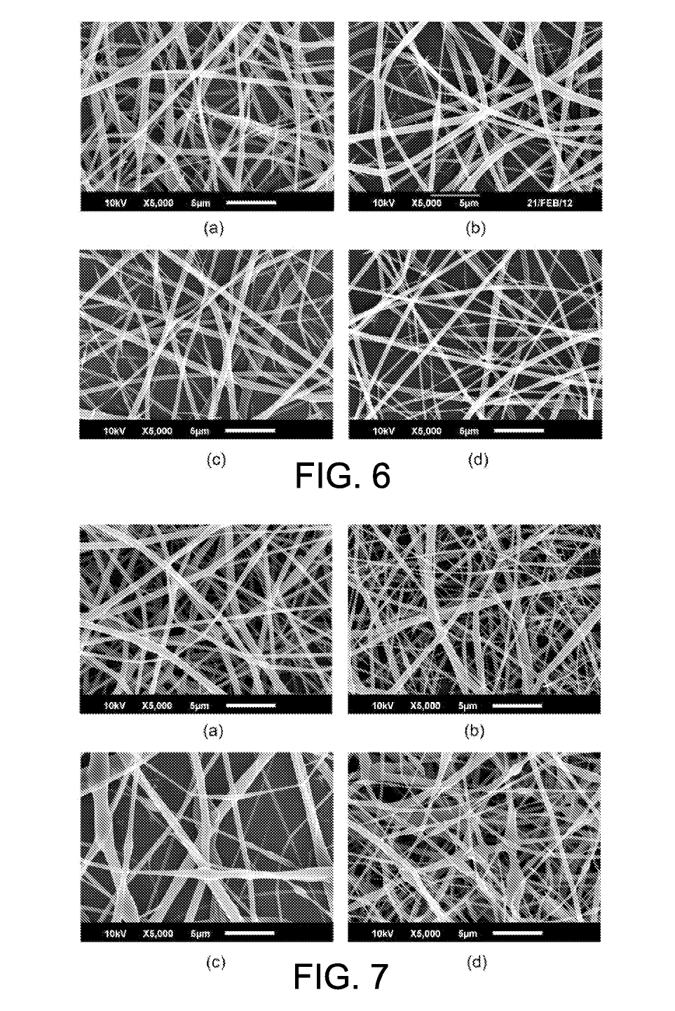

FIGS. 6 and 7 show examples of electrospun nanofibers 206 (FIGS. 2A AND 2B) collected at variable operating conditions such as nozzle voltage (Vₙ), tip-to-collector distance (TCD) and Nozzle Diameter (Dₙ). Collected nanofibers are characterized based on fiber diameter, membrane porosity and fiber distribution radii. FIG. 6 illustrates electrospun nanofiber variations at different operating conditions using only a 0.2 mm nozzle diameter Dₙ; where (a) Vₙ=12.5 kV and TCD=10 cm; (b) Vₙ=12.5 kV and TCD=12.5 cm; (c) Vₙ=15 kV and TCD=10 cm; and (d) Vₙ=15 kV and TCD=12.5 cm. At different operating voltage and distances, all nanofibers are free of beads. Characterization of the nanofibers was carried out using an image processing tool to measure the mean and standard deviation of the collected nanofibers. FIG. 7 illustrates examples of electrospun nanofiber variations for different nozzle diameters at various operating conditions with fixed TCD=7.5 cm; where (a) Vₙ=10 kV and Dₙ=0.2 mm; (b) Vₙ=12.5 kV and Dₙ=0.2 mm; (c) Vₙ=10 kV and Dₙ=0.5 mm, and (d) Vₙ=15 kV and Dₙ=0.5 mm.

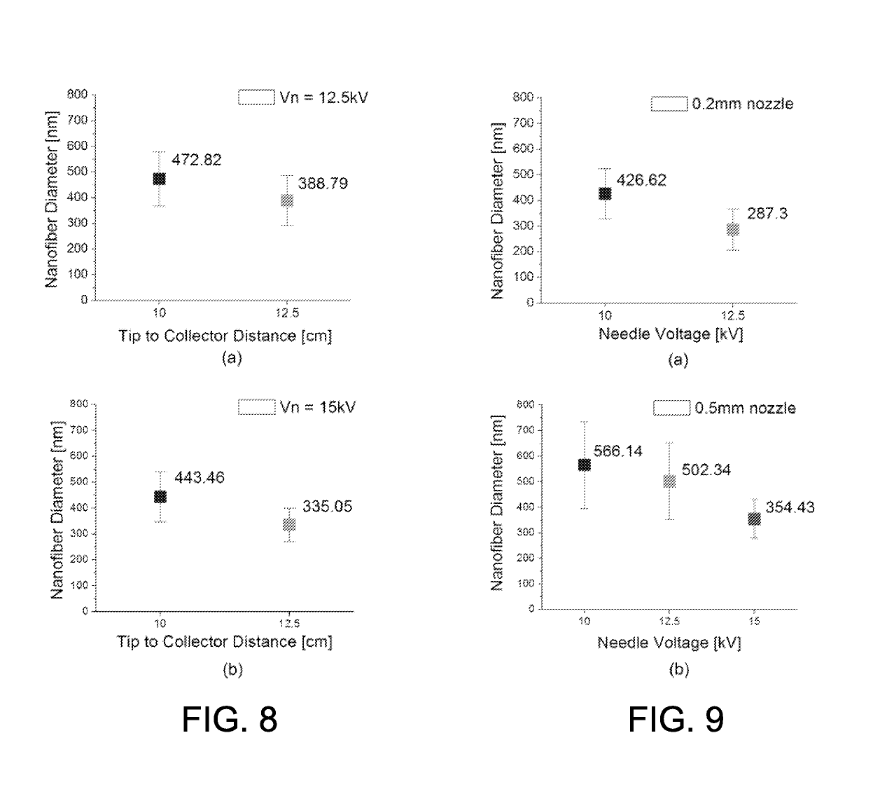

Collected nanofibers may be characterized based on fiber diameter, membrane porosity and fiber distribution radii. Nanofiber diameters of the collected nanofibers 206 (FIGS. 2A AND 2B) were measured using an Image Analysis tool (ImageJ) and graphed in FIGS. 8 and 9. FIG. 8 is an example of a plot of the mean distribution of measured TNE nanofiber diameters with a minimum sample size of 75 counts at different operating conditions with the 0.2 mm nozzle diameter Dₙ; where the needle voltage is (a) Vₙ=12.5 kV and (b) Vₙ=15 kV. FIG. 8 compares the diameters of the nanofibers collected at different operating voltages. Nanofibers collected at 12.5 kV are slightly higher in diameter than those collected at 15 kV when the operating distances are maintained the same. When the voltages are kept constant, the mean diameter of the nanofibers decreases with an increase in the operating distance. This is due to the extended distance over which the fibers are further elongated while the solvent keeps evaporating, resulting in thinner fibers.

FIG. 9 is an example of a plot of the mean distribution of measured TNE nanofiber diameters with a minimum sample size of 75 counts and with different nozzle diameters at a fixed tip-to-collector distance TCD=7.5 cm; where the nozzle diameter is (a) Dₙ=0.2 mm and (b) Dₙ=0.5 mm. Fiber diameters are compared with different nozzle diameters at different operating conditions as shown in FIG. 9. For both cases, the nanofiber diameter decreases with an increase in voltage, which may be attributed to the added charge repulsion at higher electric fields. Nanofiber diameter is also dependent on the nozzle diameter. The larger the nozzle diameter, the larger the mean diameter of the collected nanofibers. The measured diameter of the nanofiber is three orders of magnitude smaller than the nozzle diameter and it is in the range of hundreds of a nanometer, which confirms that the nanofibers collected are indeed electrospun nanofibers. For the 0.5 mm nozzle diameter, the standard deviation of the nanofibers is much larger than the nanofibers of the 0.2 mm nozzle, as can be seen in the varied nanofiber size distributions in the SEM images of the collected nanofibers. This is attributed to the unstable large polymer droplet collected at the tip of the nozzle at lower voltages. For the same 0.5 mm nozzle diameter size at 15 kV, the standard deviation is comparable to that of the 0.2 mm nozzle diameter size. This is due to the instant jetting of the droplet at the nozzle due to the higher electric field.

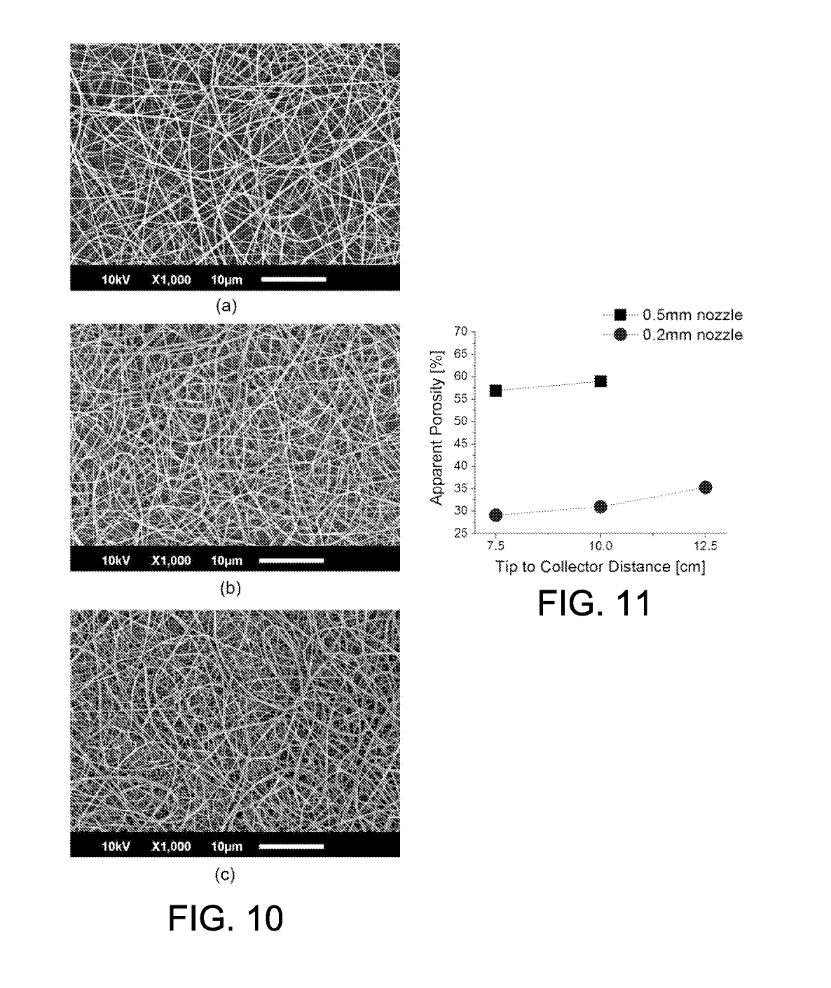

Porosity of the collected nanoporous membrane can be customized using different operating parameters. As shown in FIG. 10, porosity variations can result from using different TCDs. FIG. 10 shows porosity customization with variation in operational TCD using 0.2 mm diameter nozzles and constant needle voltage Vₙ=12.5 kV; where (a) TCD=12.5 cm; (b) TCD=10 cm; and (c) TCD=7.5 cm. As can be seen, a decrease in operational TCD allows for a denser collection of nanofibers giving a lower porosity. Using image analysis to calculate the apparent porosity of the nanoporous membrane, TABLE 1 tabulates the porosity and average pore size at different Dₙ and TCD conditions while keeping Vₙ=12.5 kV.

TABLE 1

| | | | |
|---|---|---|---|
| TCD [cm] | 7.5 | 10 | 12.5 |

Nozzle diameter = 0.2 mm

| | | | |
|---|---|---|---|
| Porosity [%] | 29.1 | 31.0 | 35.3 |
| Pore area [μm²] | 0.31 | 0.52 | 0.57 |

Nozzle diameter = 0.5 mm

| | | | |
|---|---|---|---|
| Porosity [%] | 56.9 | 59.0 | — |
| Pore area [μm²] | 0.28 | 2.46 | — |

When used for high energy density capacitors, carbon electrodes need a large surface area to volume ratio. A good measure of this property is the porosity of the nanofiber sample. Porosity of the nanofiber samples can be determined using image analysis techniques comparable to those made with standard porosity measurement techniques. FIG. 10 shows the SEM images of collected nanofibers using the 0.2 mm nozzle diameter at different TCDs with the needle voltage maintained at 12.5 kV. With a decrease in the distance between the tube nozzle and the collector, the density of fibers increases with a corresponding decrease in the porosity of the nanofiber. At shorter travel distances, the cone of electrospinning is narrowed to a smaller area over the substrate corresponding to a spatial aggregation of more nanofibers in that area. Thus, higher density fibers are collected with a shorter TCD. Binary images were produced based on the technique described earlier and the tabulated porosity and pore area measurements are shown in TABLE 1. It can be seen that a decrease in porosity of the nanofibers corresponds to a decrease in the average pore size.

FIG. 11 shows a graphical representation of an example of the porosity increment with increasing operating distances. Each condition can then be utilized for different applications for either filtration or energy density electrodes. Referring to FIG. 11, it can be seen that the porosity increases with an increase in TCD and an even larger increase with larger Dₙ. FIG. 11 provides a porosity comparison between different tube nozzle diameters that were used and their variation as a function of TCD. An increase in TCD gives increased porosity due to the increase in spread of nanofibers for a given needle voltage Vₙ. While larger nozzle diameters give larger porosities owing to the fact that larger nozzles gives larger nanofiber diameters.

In both the SNE and TNE electrospinning processes, the cone of electrospun nanofibers travel from the tip of the needle/nozzle to the substrate with an increasing radius. This radius of the collected nanofibers can then be used as a parameter in the characterization of collected nanofibers. The fiber distribution radii can be defined as the radius of the circle bounded by the line which delineates the high density from the low density fibers. TABLE 2 shows the tabulated result for the fiber distribution radius when operating voltages are different for the three nozzle TNE process with a nozzle diameter of 0.2 mm and a pitch between nozzles of 0.5 mm. Fiber distribution radii is a good measure of the nanofiber spread and is shown to increase with an increase in TCD but decrease with Vₙ as tabulated in TABLE 2. Fiber distribution radii defines the extent of nanofiber spread on a collected substrate and can be customized using different operating conditions. It can be seen that with a decrease in the operating voltage, the fiber distribution radii decrease. This may be attributed to lower electric field acting on the electrospun fiber for the given TCD and thus a smaller spread of nanofibers.

TABLE 2

| | | | |
|---|---|---|---|
| TCD [cm] | 7.5 | 10 | 12.5 |

Operating Voltage = 12.5 kV

| | | | |
|---|---|---|---|
| Radii [cm] | 5.5 | 4.5 | 8.5 |

Operating Voltage = 10 kV

| | | | |
|---|---|---|---|
| Radii [cm] | 4 | 5 | — |

For a fixed operating voltage, an increase in TCD corresponds to an increase in the fiber distribution radii. This is a natural expansion of the understanding that the larger the TCD, the wider the cone of electrospinning and thus the larger the radii. This corresponds to the previous correlation that the larger the TCD, the larger the porosity of the collected nanofibers depicted in FIG. 11. This may be attributed to the testing being operated with a constant flow rate and thus the volume of polymer used over a given time period is constant and the volume of nanofibers is constant.

Additional verification of TNE was carried out using other system configurations. For example, a LDPE tube with an outer diameter of 0.1″, an inner diameter of 0.062″, and a wall thickness of 0.02″ (Value Plastics Inc.) was used for the tube nozzle 203 (FIGS. 2A, 2B and 4), where a linear array of nozzle holes was drilled on one side of the tube nozzle 203 using a computer numerical control (CNC) milling machine (ProtoMat S100, LPKF Laser & Electronics AG, Germany). Multiple tube nozzles with permutations of different nozzle diameters (0.2 mm and/or 0.5 mm), pitch (10 mm and/or 5 mm), and count (2, 4 and/or 8) were prepared. One end of the tube nozzle 203 was thermally sealed to implement a closed system and enable to control the pressure inside the tube nozzle 203. The other end of the tube nozzle 203 was connected with a luer lock connector (Value Plastics Inc.) 409 (FIG. 4), allowing it to form easy connectivity with the syringe of the syringe pump 206 (FIGS. 2A and 2B). A copper wire was then inserted into the tube nozzle 203 on the opposite end of the nozzles and sealed with epoxy to provide ions/electrons to the polymer solution.

A fiber material of SU8 2025 was procured from Microchem Inc., which has an intrinsic viscosity of 4500 cSt with a solid content percentage of 68.45%. To prepare the solution for electrospinning, SU8 2025 was diluted in cylcopentanone (Sigma Aldrich Inc.) to a solid content percentage of 60.87%. The solution was magnetically stirred overnight and stored in dark amber bottles. Polypropylene syringes with a capacity of 3 cc (Exel International Inc. purchased through Fisher Scientific Inc.) were used to hold the polymer solution. Silicon wafers (University Wafer Inc.) were used as a substrate for nanofiber collection.

The TNE system of FIGS. 2A and 2B was used for the testing. The flow rate was determined using incremental operating voltages for different nozzle counts. An appropriate flow rate was set before the electrospinning condition switched to a dripping state for a given voltage. The investigated nozzle counts are 2, 4, and 8. The nozzle diameter was approximately 200 μm. For the 2 nozzle configuration, the operating voltage was 15 kV with the grounded collector plate placed at a tip-to-collector distance (TCD) of 12.5 cm and the flow rate was set at 0.5 ml/min. Electrospun nanofibers 206 (FIGS. 2A and 2B) were collected on a silicon substrate affixed to the collector 215 (FIGS. 2A and 2B). Silicon wafers were first cleaned with organic solvents, acetone, methanol and rinsed with deionized (DI) water. The pre-existing silicon dioxide layer was removed by immersing the silicon wafer in a diluted hydrofluoric acid solution (HF:H₂O=1:10) for 10 minutes and then rinsed thoroughly with DI water. The prepared substrate was then affixed on an aluminum plate which acted as the collector and connected to the ground knob of the power supply 212 (FIGS. 2A and 2B) through a connecting wire. Electrospinning was performed inside a custom fabricated acrylic box for controlled humidity and minimal interference of air-flow from the environment. All experiments were performed at room temperature. SU8 nanofibers were collected using a multiple intermittent electrospinning technique, which helped relax accumulated charge in the electrospun nanofibers 206 during the intermittent periods, enabling the formation of thick stacks of nanofibers over 16 cycles (each cycle has 30 sec electrospinning and 30 sec pause) to achieve 80 μm thick nanofiber membranes using a tube nozzle 203 with 8 nozzles.

Electric field simulation was performed using COMSOL Multiphysics 4.3 (COMSOL AB) to examine the electrostatic field distribution at the nozzle tips of SNE and TNE configurations and its influence on the geometry of the collected electrospun nanofibers. The diameter of the electrospun nanofibers 206 were investigated with regard to experimental parameters such as needle or nozzle voltage, tip-to-collector distance, and material properties. Analysis using the finite element method was performed to understand the effect of the spatial electric field on the repulsion of the electrospun nanofibers 206 and its relation to the semi-vertical angles. Simulation was performed on an Intel(R) Xeon(R) dual core 2.40 GHz processor with a RAM capacity of 48.0 GB. Typical optimized simulation had a mesh volume element count of about 106 with a minimum (maximum) element size of about 0.028 mm (about 2.8 mm).

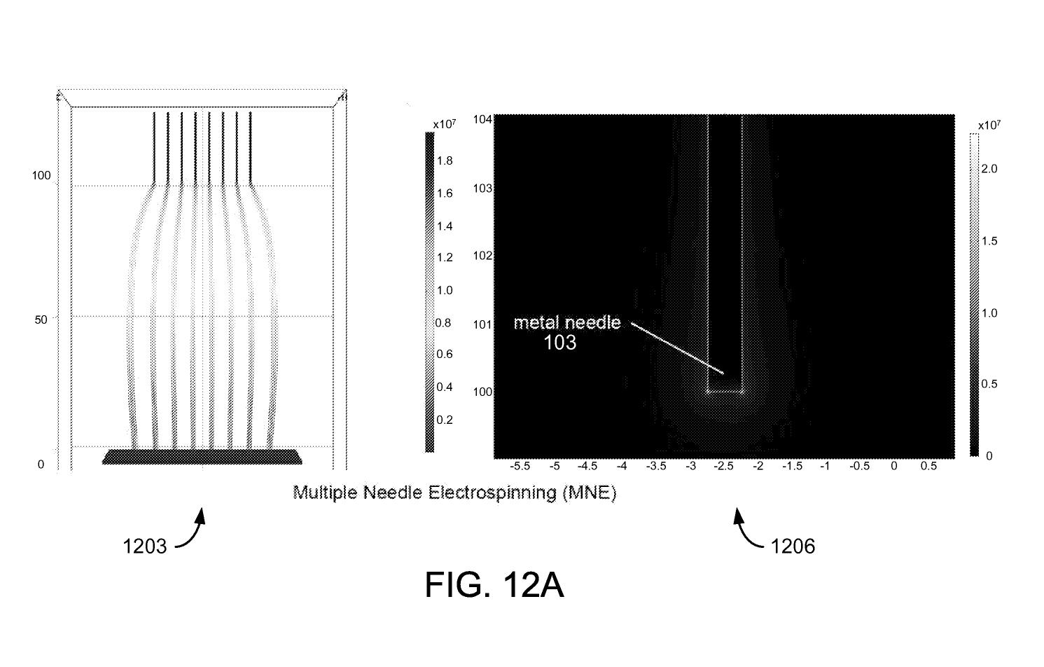

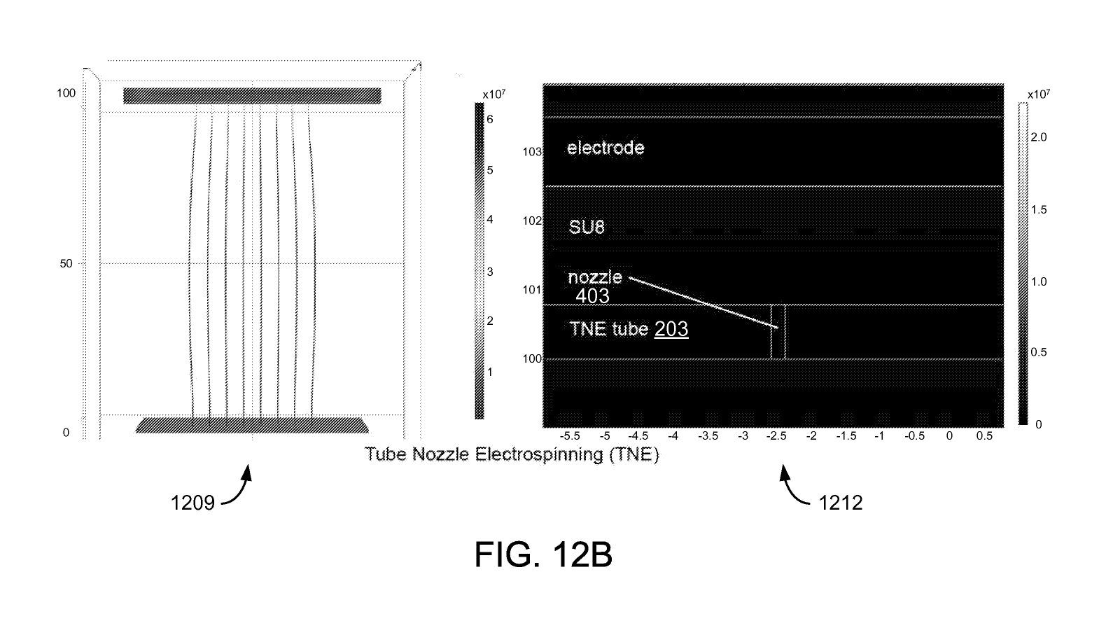

Referring to FIG. 12A, shown is (a) a three dimensional (3D) plot 1203 of electric field streamlines from the needle 103 to the grounded collector plate of the SNE system 100 (FIG. 1) with a needle voltage of Vₙ=12.5 kV and a TCD=12.5 cm and (b) the cross-section 1206 of the needle 103 showing the magnified views of the electric field strength (surface electric field norm). FIG. 12B shows (a) a three dimensional (3D) plot 1209 of electric field streamlines from a nozzle 403 to the grounded collector plate of the TNE system 200 (FIGS. 2A and 2B) with a nozzle voltage of Vₙ=20 kV and a TCD=10 cm and (b) the cross-section 1212 of the tube nozzle 203 showing the magnified views of the electric field strength (surface electric field norm). The field strength 1212 of the TNE (FIG. 12B) is approximately an order of magnitude smaller than the field strength 1206 of the SNE (FIG. 12A). As can be seen in FIG. 12B, the field streamline 1209 of the TNE is less repulsive and more parallel. The TNE system has a less dispersive deposition of the electrospun nanofibers in the collector resulting in higher density electrospun nanofibers in given time and area.

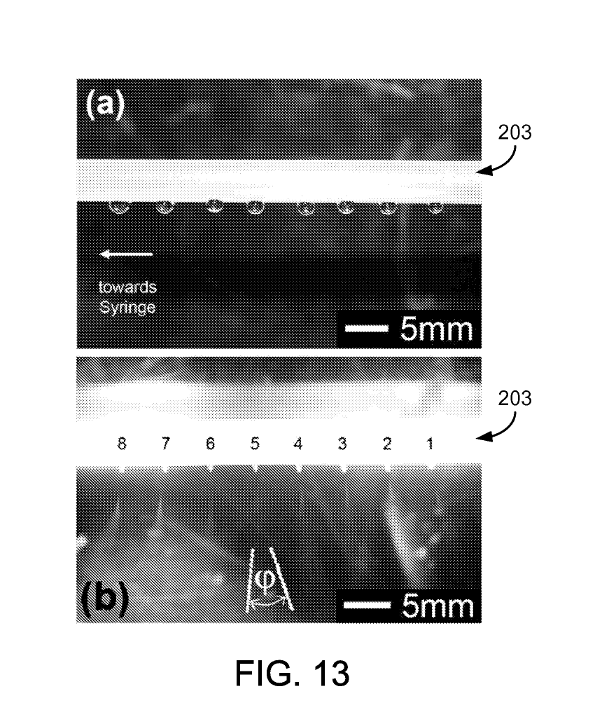

Using SNE, SU8 nanofibers in the diameter range of 200-400 nm were obtained with a flow rate of 0.2 ml/min, an operating voltage (Vₙ) of 12.5 kV, and a needle tip-to-collector distance (TCD) of 12.5 cm giving an electric field (E_{N}) of 1 kV/cm. The same operating conditions were applied in the TNE system with an increased flow rate proportional to the nozzle count. In the case of the 8 nozzle system, the flow rate was set as 1.6 ml/min, but the electric field was insufficient to begin electrospinning. Referring to FIG. 13, shown are images of the Taylor cone formation at the nozzles of the nozzle tube 203. As shown in FIG. 13(a), the electric field was insufficient to draw the Taylor cone at the tip of the nozzle, where the surface tension prevailed. Slightly increasing the operating voltage while keeping the TCD fixed, increased the electric field acting on the polymer droplet resulting in shaping it into the Taylor cone. With Vₙ=20 kV, electrospinning could be observed as shown in FIG. 13(b). As the voltage was ramped up higher, the polymer droplets were rapidly attracted to the collector while the electrospinning transitioned to dripping with a higher pumping rate. Operating conditions were maintained at the voltages and the flow rate was slightly lowered to optimize throughput.

Following the Taylor cone formation at every nozzle, the polymer droplet quickly elongated leading to a very fine jet via a bending instability stage where the nanofibers were chaotically whipped to form nanofibers. Since the Taylor cone of each nozzle is in proximity to neighboring cones, the coulombic interaction of the resultant charged nanofibers tended to push each other as shown in FIG. 13(b). The measured semi-vertical-angles (SVA), which is defined as the spread out angle (φ) from each nozzle, for 2-nozzle, 4-nozzle and 8-nozzle configurations were tabulated in TABLE 3. The repulsion effect at the nozzles located in the outer most end was the most significant showing the largest SVAs while ones located in the center showed smaller SVAs due to the repulsion forces from neighboring nozzles in opposite sides. The average SVA (24.54°) measured for an inter nozzle distance (IND) of 0.5 cm was comparable to or smaller than the SVA (30.22°) measured for the linear metallic needle architecture with an IND of 4 cm, i.e., the density of nozzles achievable with the TNE process was about a decade higher than that of a MES process. This would result in higher density nanofibers per unit area of a substrate for the given nozzle configuration.

TABLE 3

| Nozzle | | | | | | | | |
|---|---|---|---|---|---|---|---|---|
| Count | 8 | 7 | 6 | 5 | 4 | 3 | 2 | 1 |
| 2 | | | | | | | 58.34° | 45.71° |
| 4 | | | | | 48.8° | 41.3° | 42.6° | 45.4° |
| 8 | 28.37° | 25.90° | 20.58° | 21.37° | 21.49° | 24.13° | 25.14° | 29.37° |

Nanofiber characterization was performed using the scanning electron microscope (SEM, JEOL 5700, JEOL Ltd.) at the Nanoscale Research Facility for fiber distribution and morphology measurement. Nanofiber samples were sputter coated with a 20 nm thick copper film to prevent charge buildup during the imaging. Nanofiber diameters were measured from the SEM micrographs using the NIH ImageJ software (Dr. Wayne Rasband, National Inst. of Sciences, USA) at multiple locations and the mean diameter and standard deviation was determined from a sample of over 100 measurements by pixel count and comparison with the scale bar. A digital single lens reflex camera (Canon T2i, Canon USA Inc.) equipped with a standard 18/55 mm lens was used to capture the electrospinning fibers ejected from the TNE. SVA measurements were taken using ImageJ software. Electrospun nanofiber throughput measurement was determined via weight measurement using a weigh scale. Nanofiber samples collected at the end of electrospinning cycles were baked to remove residual solvents and measured and tabulated to calculate throughput. Nanofiber growth was determined by measuring the height of patterned nanofiber stacks using Profilometer (Dektak 150, Bruker Corp., USA) and measuring the average height of the nanofibrous surface.

Scanning electron microscopy (SEM) images of nanofibers were collected using TNE with a nozzle diameter (Dₙ) of 0.2 mm in different voltage (Vₙ) and tip-to-collector distance (TCD) conditions. TNE was also performed using a nozzle diameter of 0.5 mm. With the larger nozzle diameter, the mean diameters of the collected nanofibers were thicker and had a wider distribution of nanofiber diameters. Vₙ, TCD and flow rate also affect the nanofiber diameter. The effect of the operating voltage Vₙ on the fiber distribution was examined using a nozzle tube 203 with Dₙ=0.2 mm.

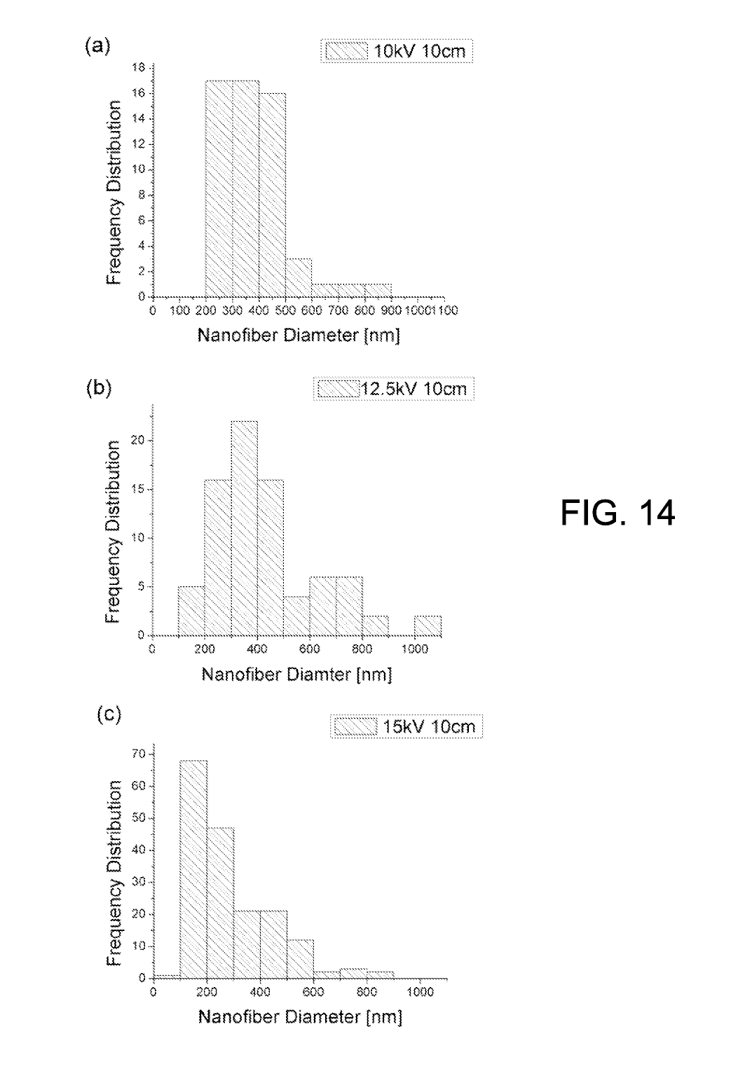

Referring to FIG. 14, shown are examples of histograms of nanofiber diameter distributions from TNE with 0.2 mm nozzle diameters and a fixed TCD=10 cm and the various operating voltages: (a) Vₙ=10 kV, (b) Vₙ=12.5 kV, and (c) Vₙ=15 kV. At lower operating voltages, the nanofiber diameters were broadly distributed from 200 nm to 500 nm. With a voltage increase to 12.5 kV, the fiber distributions appear more Gaussian like with most diameters residing in the range of about 300-400 nm, which is similar to that of SNE. With an voltage increase to 15 kV, the fiber distributions moved towards lower diameters of about 100-200 nm as the stronger electric field increases the elongation of the nanofibers.

Nanofiber throughput was calculated by the mass of electrospun nanofibers 206 collected over a certain period of time. With the 2-nozzle configurations, 16.5 mg of SU8 nanofibers was collected in a growth period of 16 mins as tabulated in TABLE 4. This gave a mass throughput of 0.03 g/hr per nozzle. In the case of the 8-nozzle configurations, the total mass throughput increased almost 8-fold to 0.46 gm/hr, which suggested that the throughput increased almost linearly with increase in nozzle count.

TABLE 4

| | Nanofiber | Time of | Substrate | Mass | Mass throughput |
|---|---|---|---|---|---|
| Nozzle | mass | collection | area | throughput | per unit substrate |
| count | (mg) | (min) | (cm²) | (ghr⁻¹) | area (ghr⁻¹m⁻²) |
| 2 | 16.5 | 16 | 54.78 | 0.06 | 10.95 |
| 4 | 66 | 16 | 54.78 | 0.25 | 45.18 |
| 8 | 124 | 16 | 54.78 | 0.46 | 83.97 |

In high density MES, characteristic bending of electrospinning jets was observed due to the electric field interaction such as coulombic interaction between neighboring jets. Due to the dispersion of nanofibers, generally thin membranes of low density nanofibers were produced. But for thick and high density nanofiber mats, high directionality of electrospinning was needed. A figure of merit to quantify the directionality of electrospinning was the mass throughput per unit area of collection. The TNE approach was observed to have a high directionality as indicated by the SVAs in TABLE 3 and also a mass throughput per unit area of 10.95 gm/hr/m² for the 2-nozzle and 83.97 gm/hr m² for the 8-nozzle as indicated in TABLE 4.

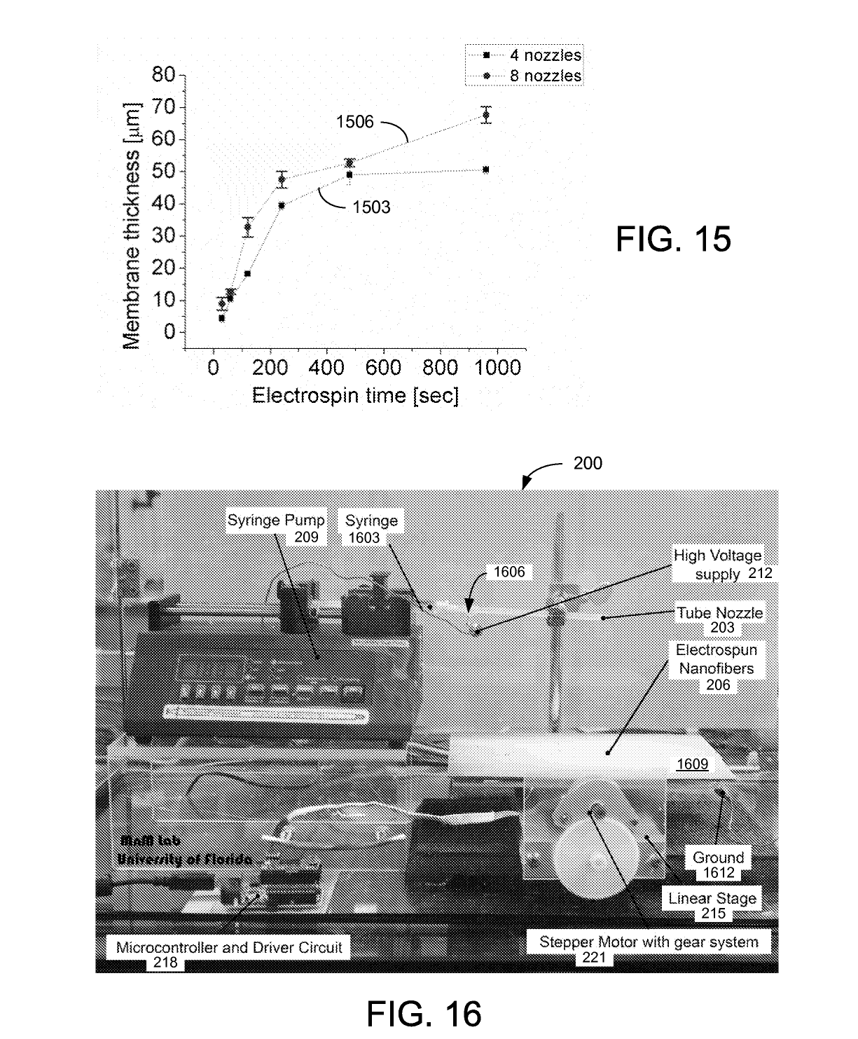

SU8 nanofibers were highly repellant as thicker stacks of nanofibers were collected, thus a multiple intermittent growth technique was used. In this technique, nanofibers were formed during growth periods with intermittent intervals of 30 seconds to allow time for accumulated charge in the electrospun nanofibers to be discharged, thus mitigating the repelling force. The TNE approach increased the nanofiber deposition rate as multiple high density nozzles squeezed the cones of electrospun nanofibers, especially located in the interior of the array. Referring to FIG. 15, shown is a plot illustrating the thickness of nanofiber stacks collected with an array of 4 and 8 nozzles (curves 1503 and 1506, respectively), which were equidistantly spaced at 0.5 mm apart. The deposition (or growth) rate increased with the increasing number of nozzles as a higher throughput of nanofibers was achieved with higher directionality. Using the 8 nozzle configuration, a growth rate of 4.7 μm/min was achieved using the multiple intermittent growth technique for an average nanofiber diameter of 300 nm. While the growth rate was observed to be linearly increasing, it started to saturate for thicker collections at 480 secs for the 4 nozzle and 8 nozzle configurations.

Referring to FIG. 16, shown is an example of an actual assembly of the TNE system 200 of FIGS. 2A and 2B. Fabricated nozzles 403 (FIG. 4) on one end of a nozzle tube 203 are supplied by a syringe 1603 which is pumped by the syringe pump 209. Due to the voltage applied by the high voltage supply 212 via a connection to the electrode wire 1606 inserted into the nozzle tube 203 and the substrate 1609 mounted on the stage 215 and grounded by ground connection 1612, electrospun nanofibers 206 are collected on the substrate 1609. A microcontroller 218 programmed stepper motor 221 moves the substrate 1609 on the stage 215 based on a predefined program to uniformly collect the electrospun nanofibers 206. In other embodiments, the stage 215 may be controlled in multiple directions. In the example of FIG. 16, a 6″×8″ substrate 1609 is shown uniformly covered with electrospun SU8 nanofibers 206.

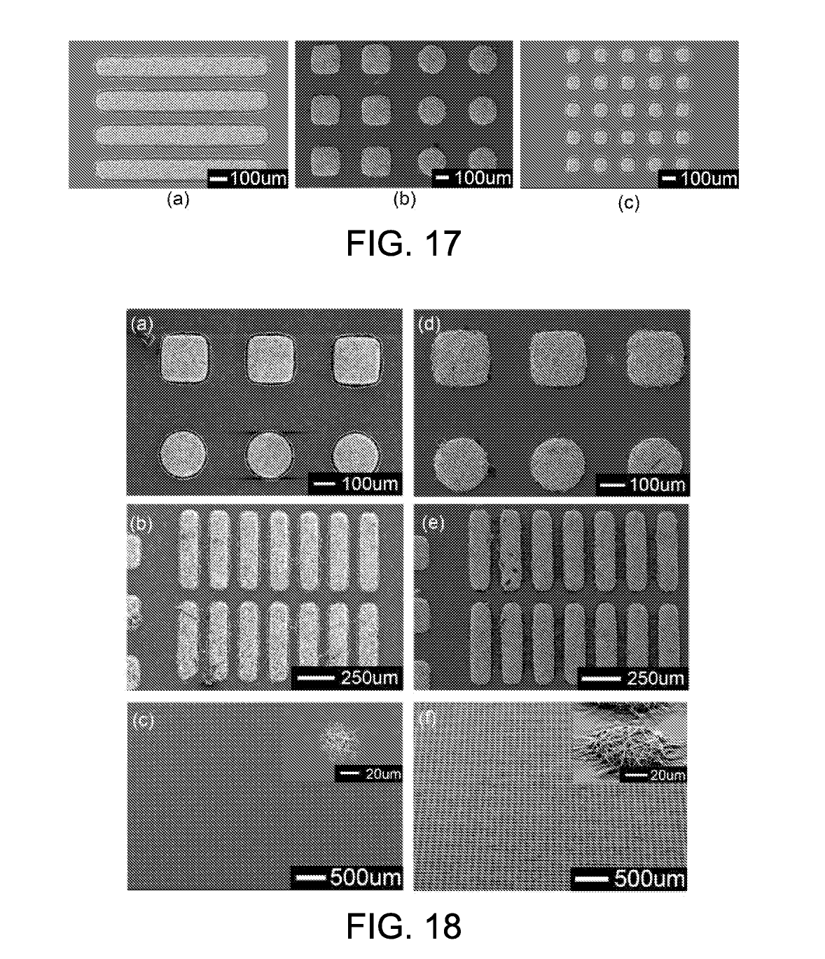

The spatial distribution corresponding to specific operating conditions may also be taken into account when stitching large areas of electrospun nanofibers 203 for a uniform distribution. The stepper motor 221 driven stage 215 can be used in the case of large scale manufacturability of the TNE process. The microcontroller 218 can be programmed to move the stage 215 in a predefined length based on, e.g., parameters in TABLE 2, which correspond to stepping the motor at a specified number of steps. Electrospun SU8 nanofibers 206 may be collected on individual silicon wafers 1609 and lithographically patterned. Referring to FIG. 17, shown are top views of examples of lithographically patterned SU8 nanofibers. The electrospun nanofibers 206 collected on the substrate 1609 of FIG. 16 can be patterned using a standard UV (i-line) lithography process to give different patterns in the nanoporous membrane using a single lithography mask. This may be followed by a carbonization process to produce carbon nanofibers. FIG. 17 depicts (a) rectangular patterns (about 1 mm×0.1 mm); (b) squares (about 0.2 mm×0.2 mm) and circles (about 0.2 mm diameter); and (c) circles (about 0.1 mm diameter). Other shapes such as, e.g., crosses or more complicated designs may also be patterned to shape the electrospun nanofibers 206.

Since electrospun SU8 nanofibers are photopatternable, the collected stacks of nanofibers can be photolithographically patterned into microscopic shapes. While the photolithography can be performed on a non-smooth surface, the patterning resolution may be compromised. FIG. 18 compares the effect of UV dosage on the height of various patterned SU8 nanofiber stacks. FIG. 18 incudes SEM images of patterned thick nanofiber stacks of different heights or thicknesses: (a-c) 20 μm, (d-e) 60 μm and (f) 40 μm. FIGS. 18(a) and 18(b) show 20 μm thick nanofiber stacks exposed with a 240 mJ/cm² dosage. An over-dosage effect was observed at the edge of each structure with a darker halo like pattern. FIGS. 18(d) and 18(e) are 60 μm thick patterns exposed with a 240 mJ/cm² showing no halo pattern. For high density patterns such as those in FIGS. 18(e) and 18(f), low lying nanofibers were observed to be interconnected at certain points. This artifact may be attributed to the diffraction effect during exposure since the diameter of the nanofibers was in the range of the wavelength of the UV source (i-line, λ=365 nm). Patterns with diameters of 20 μm and 40 μm were patterned with SU8 nanofibers shown in the insets of FIGS. 18(c) and 18(f), respectively. High density patterns may need a higher uniformity on the surface of the nanofiber prior to exposure. With the presence of bump or liquid drops of SU8, an enlarge proximity gap between the mask and resist can result in pattern enlargement or deformation due to diffraction of the UV light.

TNE with an LDPE tube and multiple nozzles was successfully demonstrated, which offered excellent production capabilities with reduced repulsion of nanofibers in favor of high throughput production of nanofibers. The use of multiple nozzles on a plastic tube allows for improved directionality of electrospinning having a low SVA of 24.54° due to the reduced coulombic repulsion of electrospinning cones in the 8-nozzle configuration. Nanofiber diameters were in a range similar to those of SNE and were tunable with operating voltage and TCD. The diameters of the electrospun nanofibers produced with high electric fields were smaller than those of low electric field, which may be attributed to the high elongation force to the nanofibers in the high electric field. Using a 8-nozzle configuration, TNE demonstrated a high nanofiber collection rate of 83.97 gm/hr/m² showing a high production rate that was dependent on nozzle count. Improved directionality of electrospinning with TNE allowed for thick stacks of SU8 nanofibers to be fabricated. The growth rate of SU8 nanofiber stacks exhibited saturation due to the accumulated charge in the nanofibers. The multiple intermittent growth technique was able to mitigate the accumulated charge. The 8-nozzle stack growth rate of 83.97 gm/hr/m² was approximately an 8-fold increase over the 2-nozzle TNE growth rate of 10.95 gm/hr/m². Lithographic patterning of thick SU8 nanofibers may be affected by the smoothness of the nanofiber surface. The diameter of the electrospun nanofibers is in the range of the wavelength of the UV source, which may result in the patterning resolution being limited by the diffraction effect. TNE showed to be an excellent nanofiber manufacturing approach with low repulsion electrospinning, high throughput production, and high stack growth rate. It also showed low operating voltages comparable to SNE, the compatibility with an existing SNE system, and material saving compared with the open environment needless electrospinning approach.

As mentioned above, the TNE process may be used to fabricate carbon nanofiber (CNF) electrodes for high energy density capacitors or super capacitors (SCs). Such energy storage devices may be used to capture sudden spikes in energy generated over short time periods during, e.g., automobile regenerative braking or for non-conventional energy storage. The TNE process may be used to produce porous electrodes and/or charge separation materials for the construction of high energy density or super capacitors. Polymeric fibers with diameters in the nanometer range and nanoporous membranes with a very large surface area can be produced by TNE. Carbonization can be used to transform the polymeric nanofiber to CNF making it an excellent porous electrode material. Such carbon nanofibers may be used as electrodes for SCs without dielectric material coated, which in fact provides much higher capacitance density. Electrospun SU8 nanofiber membranes produced by TNE may also be used as the separator for SCs.

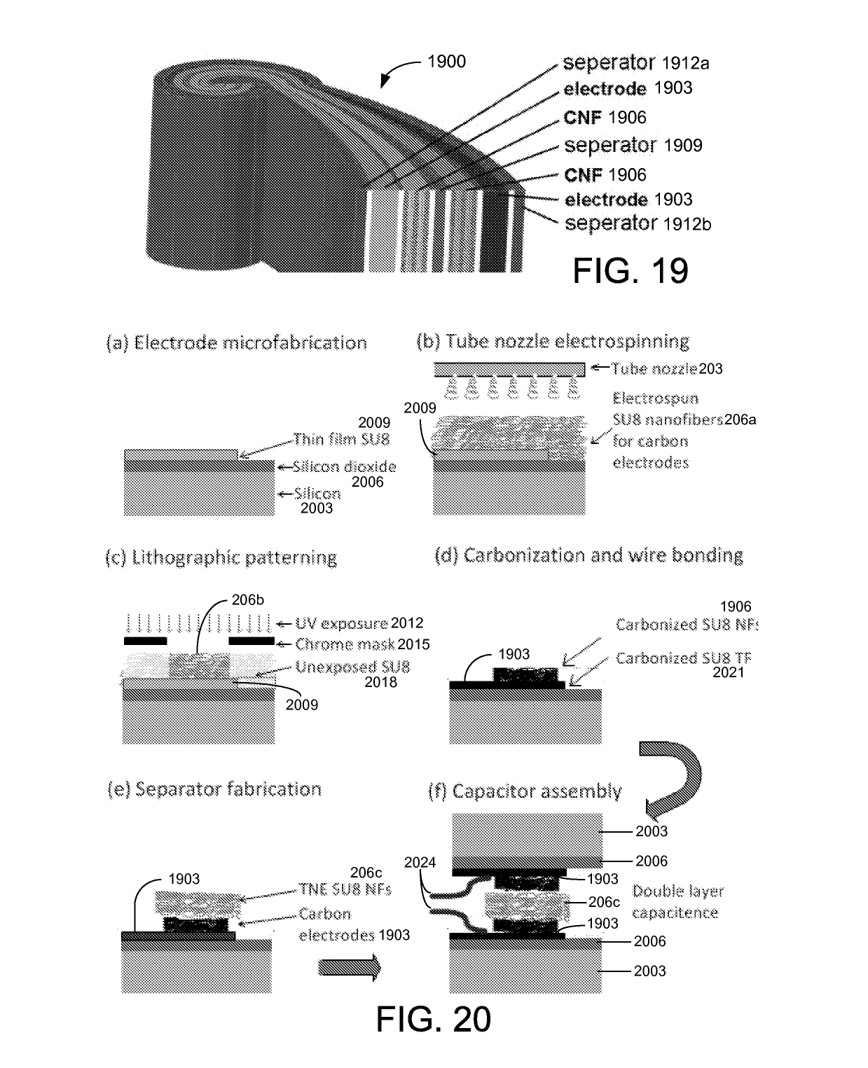

Referring to FIG. 19, shown is a graphical representation of an example of a super capacitor (SC) 1900 with electrodes of CNF separated by an electrospun nanofiber membrane. The SC 1900 includes two electrodes 1903, each including CNF 1906. A separator 1909 (e.g., of electrospun nanofiber) is disposed between the CNF 1906 to provide a charge separation mechanism between the two electrodes 1903. The ion transfer length determined by the spacing between the electrodes can be minimized with the use of a electrospun nanofiber separator 1909. In the example of FIG. 19, separators 1912a and 1912b are disposed on the electrodes 1903 opposite the CNF 1906. The integrated fabrication of the SC 1900 allows for a compact design which may be scaled up by rolling the capacitor as illustrated in FIG. 19. In some embodiments, a single separator (e.g., 1912a) may be used to provide separation between the electrodes 1903 when the SC 1900 is rolled up.

Referring to next to FIG. 20, shown is an example of a SC fabrication process using TNE. The fabricated SC includes carbon nanofibers as porous electrodes and an electrospun SU8 nanofiber membrane as the separator between the electrodes. Beginning with FIG. 20(a), a substrate is prepared. For example, a silicon substrate 2003 (e.g., University Wafers Inc., USA) can be insulated with the deposition of silicon dioxide 2006 (e.g., 900 nm, 13.56 MHz, PECVD, STS 310PC). A base electrode pattern may then be formed from, e.g., a 7 μm SU8 thin film 2009 (2005, Microchem Inc., Newton, Mass.) that is spin coated and patterned. Next, in FIG. 20(b) electrospun nanofibers 206a are deposited on the base electrode pattern 2009 from a tube nozzle 203 of, e.g., the TNE system of FIGS. 2A and 2B. For example, non-woven SU8 nanofibers 206a can be electrospun on the base electrode pattern 2009 by TNE using SU8 with a solid concentration of, e.g., 60.87 wt/v % in a solvent of cyclopentanone (Sigma Aldrich, St. Louis, USA). The TNE process may use an 8-nozzle array with a nozzle voltage of, e.g., Vₙ=15 kV (DEL HVPS MOD 603 30 KV POS, Spellman High Voltage Electronic Corp., USA) and a tip-to-collector distance (TCD) of 15 cm. As previously discussed, the 8 nozzles can be made on the side wall of a LDPE tube with a nozzle diameter of 0.2 mm and a pitch between the nozzles of 5 mm using a milling machine (S100 Protomat, LPKF Laser & Electronics, Tualatin, Oreg.).

Lithographic patterning of the electrospun nanofibers 206a is next performed in FIG. 20(c). Electrode patterns similar to the base electrode pattern 2009 can be photodefined by standard UV lithography using a Mask Aligner (MA-6, Karl Suss). For example, lithographic patterning can be performed using UV exposure 2012 through a chrome patterned glass mask 2015 and immersion and rinse processes can remove the unexposed SU8 nanofibers 2018. In FIG. 20(d), the base electrode pattern 2009 and the patterned nanofiber stack 206b of FIG. 20(c) is carbonized in, e.g., a tube furnace (F79345, Thermolyne Inc., USA) with an inert atmosphere to produce the carbonized electrode 1903 including carbon nanofibers (CNF) 1906 on the carbonized thin film 2021. A steady formine gas flow (5% H2, balance N2) is maintained in the tube furnace at 2 slm (Matheson flow meter) with a pyrolysis temperature between about 900-1000° C. A pair of electrodes 1903 may be formed in this fashion.

In FIG. 20(e), electrospun nanofibers 206c are deposited on one of the pair of electrodes 1903 using TNE. For example, a 40 μm thick layer of SU8 nanofibers can be electrospun from the tube nozzle 203 as described for FIG. 20(b). The two electrodes may then be sandwiched together and assembled with the separator defining the gap between the electrodes as shown in FIG. 20(f). The SC assembly can then be immersed in an electrolytic bath (e.g., Copper Sulphate/Boric Acid solution) under a modest vacuum to seep the nanofiber electrodes and the separator before packaging and testing. Leads 2024 may be connected to the carbonized thin film 2021 of the electrodes 1903. In some implementations, the silicon wafer 2003 and/or silicon dioxide 2006 may act as a separator 1912. In other embodiments, the silicon wafer 2003 and/or silicon dioxide 2006 may be removed and an electrospun nanofiber membrane may be used as the separator 1912.

Nanofiber characterization was performed to determine the morphology and dimensions using a scanning electron microscope (SEM). Electrospun SU8 nanofibers were sputtered prior to imaging with a 50 nm copper thin film (KJL CMS-18 Multi-Source, Kurt J. Lesker, Livermore, Calif.) and imaged using a field emission SEM (SU-70, Hitachi Inc., Japan). Carbon nanofibers were imaged without metal coating. Nanofiber membrane height was measured using a profilometer (Dektak 150, Bruker AXS, Tuscon, Ariz.). The nanofiber diameters in the SEM images were measured using image analysis software (ImageJ, National Institutes of Health, USA). Capacitance measurements of fabricated SCs were performed using a function generator (Agilent 331020A, Santa Clara, Calif.) and an oscilloscope (Tektronix 2014, Beaverton, Oreg.).

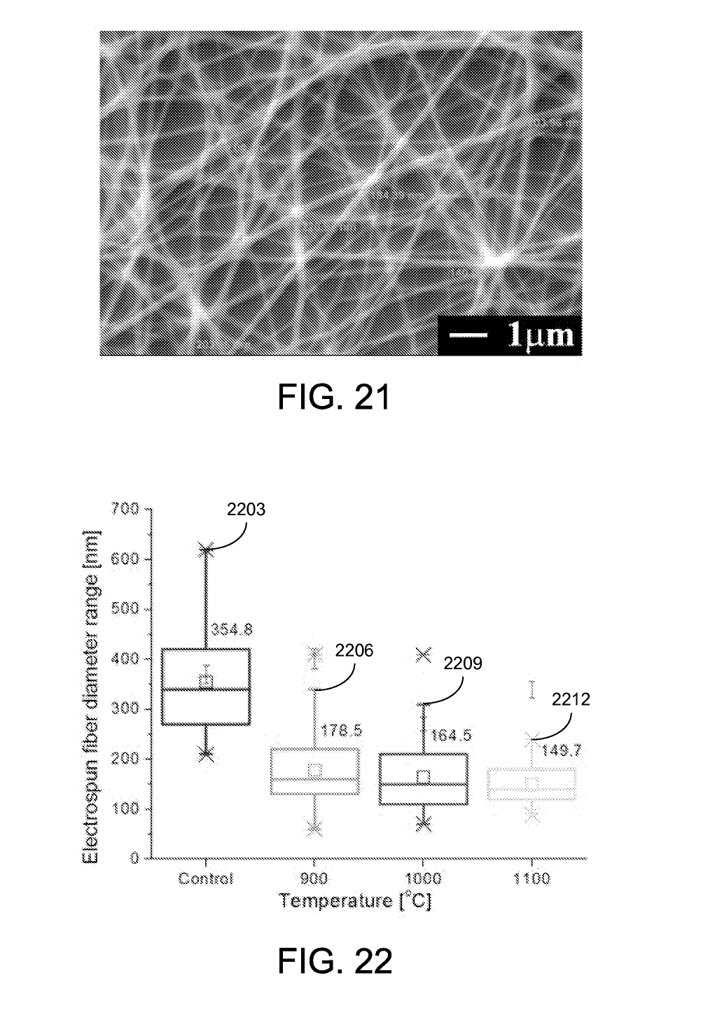

Referring to FIG. 21, shown is a SEM image of carbonized SU8 nanofibers. After the carbonization of the SU8 nanofibers 206b (FIG. 29(c)), the resultant carbon nanofibers 1906 (FIG. 29(d)) were observed to shrink in diameter. FIG. 22 is a plot illustrating the diameter shrinkage observed in the carbon nanofibers with incremental carbonization temperatures. Electrospun SU8 nanofibers with an average diameter of about 354.8 nm (bar 2203) decreased in diameter to about 178.5 nm (bar 2206), about 164.5 nm (bar 2209) and about 149.7 nm (bar 2212) when carbonized at 900° C., 1000° C. and 1100° C., respectively. This may be attributed to the loss of elemental oxygen and hydrogen during carbonization, which makes up 60% of the polymer in the thin film SUB. The shrinkage in the carbon nanofiber diameter can be counterproductive in the case of a SC as it reduces the electrode surface area. Thus, an increase in the nanofiber throughput and packing density to compensate for the reduced surface area is desirable.

TNE can be used to increase the nanofiber throughput for the fabrication of thicker nanofiber stacks, which counters the carbon shrinkage. TNE can also be used for the nanofiber separator fabrication. FIGS. 2A and 2B show a schematic diagram of an example of the TNE setup wherein, a tube nozzle 203 is used as a polymer reservoir and the nozzles fabricated in the tube nozzle 203 act as jetting sources for the electrospinning cones. A higher nozzle count can increase the nanofiber throughput, although the nanofiber cones are observed to repel each other as observed in FIG. 13(b). A measure of the repulsion is the semi-vertical angle (SVA) which quantifies the angle (φ) of the electrospinning cone to quantify the repulsion. Since large SVAs imply large repulsion between the cones, a small SVA is desired in the fabrication of thicker membrane stacks needed for the thick porous electrode in a given area.

Nanofiber stacks using the 2, 4, and 8 nozzle configurations were tested and their SVAs were measured by an image analysis tool. For a 2 nozzle array, the electrospinning cones were very divergent and similar to single needle electrospinning SVAs. For the 4 and 8 nozzle configurations, a decreasing trend in the SVA from the outer nozzles to the inner nozzles was observed. This may be attributed to the fiber repulsion in the high density nozzle configurations. The higher the nozzle count, the smaller the SVAs on the Taylor cones, thus a higher density of nanofibers can be deposited in a given electrode area.

While high density nozzles increase the nanofiber throughput with decreased SVAs, nanofibers do experience repulsion until they reach the substrate. The thickness of the nanofiber stacks was measured as a function of time for 4 and 8 nozzle TNE. Referring to FIG. 15, curves 1503 and 1506 of the plot illustrate the thickness of nanofiber stacks collected with an array of 4 and 8 nozzles, respectively. The stack growth rate increases with a higher nozzle count as expected with higher mass throughput. While the stack thicknesses gradually increased, saturation in the growth rate was observed in both nozzle configurations. This may be the effect of repulsion associated with charge accumulation at the collected nanofibers.

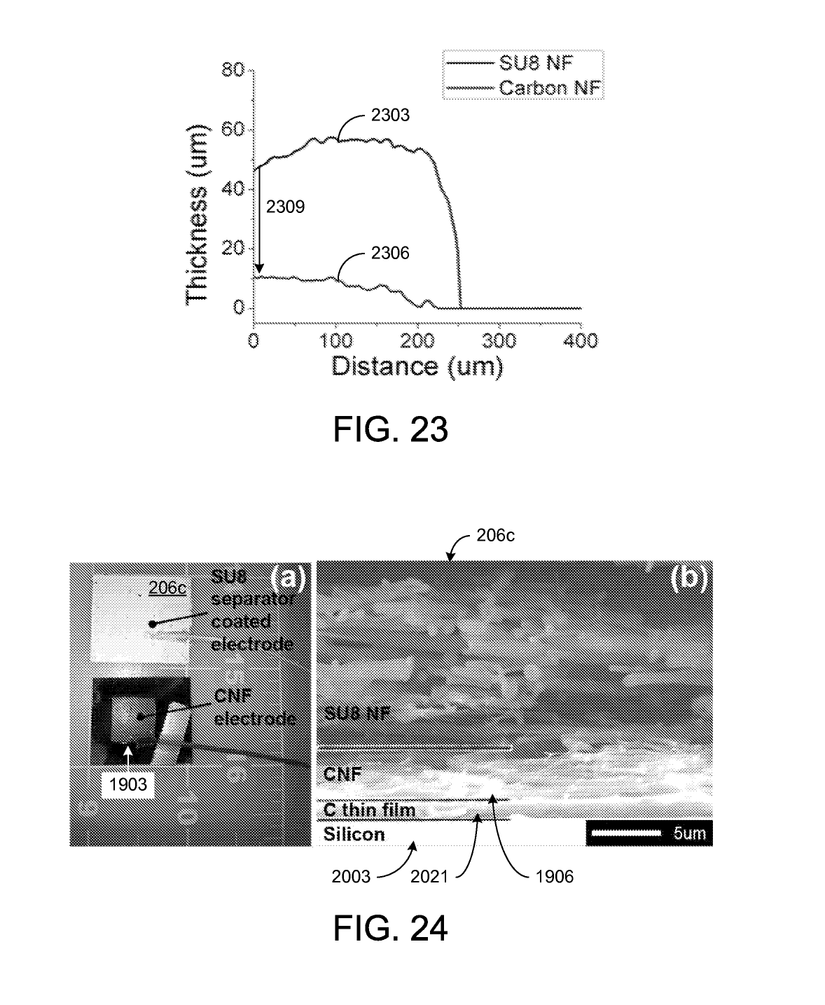

Referring to FIG. 23, shown is a plot illustrating the shrinkage of the thickness of an electrospun nanofiber membrane with carbonization. The SU8 nanofiber stacks followed by carbonization were observed to shrink in height as shown in FIG. 23. A 48 μm thick SU8 membrane (curve 2303) shrinks to 10 μm thick (curve 2306) when carbonized at 900° C. The shrinkage in thickness 2309 of the membrane may be attributed to the combination of nanofiber diameter shrinkage and air gap shrinkage.

FIG. 24 includes images of examples of a fabricated CNF electrode and separator for a SC. FIG. 24(a) shows images of an unpackaged SC including the fabricated CNF electrode 1903 (bottom) and the CNF electrode 1093 coated with the electropsun SU8 nanofiber separator 206c (top) before the final assembly. FIG. 24(b) shows a SEM image of the cross-section of the fabricated SC, wherein the multiple layers of nanofibers are sandwiched tightly to give a compact SC. The observed layers include the silicon 2003, carbonized thin film 2021, CNFs 1906, and SU8 nanofibers 206c. The overall height of the SC including the separator was 54 μm. Capacitance of the fabricated capacitor was tested using an oscilloscope and a function generator, resulting in a maximum 450 nF/mm². This is one of the thinnest SCs reported for this capacity range.

Tube Nozzle Electrospinning (TNE) for the production of large electrospun nanofibers has been discussed. A semi-automated tube fabrication system may be used to produce electrospun nanofibers with repeatable performance. With the use of multiple nozzles, production capacity can be increased without the need for additional equipment or significantly higher operating voltages. Porosity and pore area calculations by image analysis support the use of TNE produced nanofibers for high energy density capacitor applications. The nanomanufacturing capability has been demonstrated with large area electrospun nanofibers collected on a substrate integrated with or affixed to a microcontrolled linear stage. The nanofibers can be patterned with lithographical precision and carbonized to give carbon nanofibers.

Electrospun nanofibers 206 may be used in a variety of applications including, e.g., electrodes in energy storage devices, bio-scaffolds using biocompatible polymers such as, e.g., PLGA, PLA, PGA, PCL, collagen, agarose cellulose, sugar, etc., filter membranes with customizable porosities for used in liquid and gas filtration, and uniform membranes for gas sensors. Advantages of the TNE system 200 can include lower operating voltages than current electrospinning techniques resulting in reduced voltage and power requirements, reduced cost by using an LDPE tube instead of metallic needles, compatibility with existing electrospinning equipment, a closed channel architecture with minimal inactive-polymer matrix allows savings in electrospun polymer, independent of the flexibility of the substrate, and nozzle tube production can provide a reliable source of replacement parts.

An all-nanofiber based fabrication process for a super capacitor (SC) using carbon nanofibers (CNF) for electrodes and electrospun SU8 nanofibers for a separator has been demonstrated. Using TNE allows a higher density of electrospun nanofibers due to smaller SVAs of electrospinning jets resulting in the fabrication of thicker layers of CNF. CNF based electrodes are advantageous because of the larger surface area, chemical resistance and higher conductivity. Meanwhile SU8 nanofiber separators give faster ion transfer, chemical and mechanical stability.

It should be emphasized that the above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

It should be noted that ratios, concentrations, amounts, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1% to about 5%” should be interpreted to include not only the explicitly recited concentration of about 0.1 wt % to about 5 wt %, but also include individual concentrations (e.g., 1%, 2%, 3%, and 4%) and the sub-ranges (e.g., 0.5%, 1.1%, 2.2%, 3.3%, and 4.4%) within the indicated range. The term “about” can include traditional rounding according to significant figures of numerical values. In addition, the phrase “about ‘x’ to ‘y’” includes “about ‘x’ to about ‘y’”.

Therefore, at least the following is claimed:

1. A system, comprising:
a nozzle tube including an array of nozzles configured to produce a plurality of electrospun nanofibers; and
a positioning stage configured to control deposition of the plurality of electrospun nanofibers on a substrate to form a layer of nanofibers.

2. The system of claim 1, wherein the nozzle tube comprises a high voltage probe mounted adjacent to the array of nozzles.

3. The system of claim 2, wherein the high voltage probe is sealed within the nozzle tube.

4. The system of claim 2, further comprising a high voltage supply coupled to the high voltage probe.

5. The system of claim 1, further comprising a pump coupled to the nozzle tube opposite the array of nozzles, the pump configured to provide nanofiber material to the array of nozzles via the nozzle tube.

6. The system of claim 1, further comprising a drive system for controlling movement of the positioning stage.

7. The system of claim 6, wherein the drive system comprises a stepper motor for controlling linear movement of the positioning stage.

8. The system of claim 6, wherein the drive system comprises a microcontroller configured to direct movement of the positioning stage based upon a predefined program.

9. The system of claim 8, wherein the drive system further comprises memory to store the predefined program.

10. The system of claim 6, wherein the drive system is configured to control movement of the positioning stage in multiple directions.

11. The system of claim 1, wherein the nozzle tube comprises a non-conductive material.

12. The system of claim 11, wherein the nozzle tube comprises low density polyethylene (LDPE).

13. The system of claim 1, wherein the array of nozzles is a linear array comprising a plurality of nozzles separated by a uniform distance.

14. A method, comprising:
generating a plurality of electrospun nanofibers from an array of nozzles positioned over a substrate; and
controlling movement of the substrate to form a layer of electrospun nanofibers.

15. The method of claim 14, further comprising controlling voltage applied at the array of nozzles to control diameter of the plurality of electrospun nanofibers.

16. The method of claim 14, further comprising controlling distance between the array of nozzles and the substrate to control diameter of the plurality of electrospun nanofibers.

17. The method of claim 14, further comprising patterning the layer of electrospun nanofibers.

18. The method of claim 17, wherein the layer of electrospun nanofibers is patterned using a UV lithography process.

19. The method of claim 18, wherein the patterned electrospun nanofibers are carbonized to form patterned carbon nanofibers.
